(19) United States
(12) Patent Application Publication
(10) Pub. No.: US 2006/0076640 A1
(43) Pub. Date: Apr. 13, 2006

(54) Semiconductor device

(75) Inventors: Peter Blair, Chadderton (GB); Paul Jerred, Chadderton (GB); Kevin Lowe, Chadderton (GB); Lee Riley, Chadderton (GB)

Correspondence Address: FOLEY & LARDNER, 2029 CENTURY PARK EAST, SUITE 3500, LOS ANGELES, CA, 90067, US

(73) Assignee: Zetex Plc

(21) Appl. No.: 11/191,607

(22) Filed: Jul. 28, 2005

(30) Foreign Application Priority Data
Jul. 30, 2004 (GB) 0417024.7

(51) Int. Cl. H01L 29/00

(52) U.S. Cl. 257/506; 257/510; 257/521

(57) ABSTRACT

A semiconductor device, comprising a trench extending into the device from a surface. The trench has sidewalls extending along the length of the trench, a depth and a width defined at said surface between said sidewalls. The trench is at least partly filled with a material. At least one of the sidewalls is provided with at least one lateral recess, the or each recess providing a discrete localised increase in said trench width.

### CROSS-REFERENCE TO RELATED PATENT APPLICATIONS

Great Britain Priority Application 0417024.7, filed Jul. 30, 2004, including the specification, drawings, claims and abstract, is incorporated herein by reference in its entirety.

The present invention relates to semiconductor devices and methods of fabricating semiconductor devices. In particular, but not exclusively, this invention relates to semiconductor devices comprising trenches filled with conductive material.

In the production of semiconductor devices it is frequently necessary to form trenches in the surface of a semiconductor substrate extending into the substrate. The trench may then commonly be filled with a different material. For example, within devices such as Metal Oxide Semiconductor Field Effect Transistors (MOSFET) and Insulated Gate Bipolar Transistors (IGBT) trenches may be formed to intersect one or more layers of material within the device. For instance, this process may be used to form a gate trench for a ‘U’ shaped trench MOSFET (UMOS) transistor, whereby a ‘U’ shaped trench is etched through the upper surface of the semiconductor substrate, into the body of the substrate, and then wholly or partially filled with a conductive material. This conductive material may be polysilicon.

A trench extending into a semiconductor substrate may be formed by, for instance, reactive ion etching. High-energy ions are fired at the surface of the substrate. A mask is placed between the ion source and the substrate, such that the beam of ions incident upon the surface of the substrate is patterned. The shape of the trenches and other etched features are determined by the pattern of the mask. The depth of each trench is determined by the length of time that part of the substrate is exposed to the ion beam.

The aspect ratio of a trench is defined as the depth of the trench, divided by the width of the trench. A trench may be substantially rectilinear, with vertical sidewalls and a horizontal trench base. Alternatively, the sidewalls may be inclined to a horizontal base or may meet at a line at the base of the trench forming a “V” shape. The angle of the sidewall, with respect to the surface of the substrate, is dependent upon the relative position of the ion source and the substrate. Due to manufacturing tolerances, trenches that are required to have sidewalls substantially normal to the surface of the substrate may in fact be overhanging. Alternatively, for some devices, overhanging sidewalls may be required.

Polysilicon is typically deposited in the trenches by chemical vapour deposition. Chemical vapour deposition is a process whereby polysilicon in the form of a gas is delivered into a reaction chamber containing the semiconductor substrate. As the gas comes into contact with the substrate it reacts forming a solid residue that is deposited onto the surface of the substrate. The solid deposit is laid down in layers, approximately uniformly.

However, when using chemical vapour deposition to deposit polysilicon in a trench, there is a tendency for polysilicon to be deposited preferentially at the upper edges of the trench. The upper edges of the trench are closer to the source of the polysilicon than the base and sidewalls of the trench, therefore the upper edges of the trench are exposed to a greater flow of gas. This can lead to the opening of the trench being closed off, before the lower part of the trench has been completely filled. This creates trapped voids within the polysilicon.

Additionally, the problem of the opening of the trench closing off before the lower part has completely filled is increased as the sidewalls of the trench become steeper. If the sidewalls of the trench are overhanging the problem can become acute.

The problem of trapped voids increases as the aspect ratio of the trench increases. This is because, for a given width of trench, the trench opening will close off as described above at a constant rate. However, the deeper the trench, the greater the probability that at least part of the lower portion of the trench will remain unfilled when the opening to the trench closes.

Voids in the polysilicon, if of a sufficient size or in a position such that they come close to the sidewall of the trench, can lead to uncontrolled charge at the sidewall within the body of the semiconductor substrate. This is because the charge of the sidewall of a trench is at least partially determined by electrostatically-induced charge build-up caused by the material within the trench. This transfer of charge is reduced if there is a void between the sidewall and the material within the trench. Uncontrolled charge at the sidewall may allow unwanted and uncontrolled leakage currents to flow through the semiconductor device. In the case of trench MOSFETs these leakage currents may flow alongside the sidewall of the gate trench between the drain and the source of the device, even when the device is in the blocking mode. When the device is in the blocking mode no leakage should occur.

Further processing of the semiconductor device, for instance during annealing, is liable to cause the voids to coalesce and/or migrate towards the sidewalls of the trench exacerbating the problem.

It is an object of the present invention to obviate, or mitigate, the above disadvantages.

According to a first aspect of the present invention there is provided a semiconductor device, comprising a trench, extending into the device from a surface, the trench having sidewalls extending along the length of the trench, the trench having a depth, the trench having a width defined at said surface between said sidewalls, and the trench being at least partly filled with a material, wherein at least one of the sidewalls is provided with at least one lateral recess, the or each recess providing a discrete localised increase in said trench width.

According to a second aspect of the present invention there is provided a method of fabricating a semiconductor device, the method comprising forming a trench extending from a first surface of the device the trench having sidewalls extending to a depth below the surface, and having a width defined at said surface between said sidewalls, at least one of the sidewalls being provided with at least one localised recess, the or each recess providing a discrete localised increase in said trench width, and at least partly filling the trench with a first material by chemical vapour deposition.

An advantage of the present invention is that during filling of the trench by chemical vapour deposition the or each recess will remain open to deposition of material even if the openings of other portions of the trench are closed off due to preferential deposition of material. Consequently a route is left open through which reactive gases may pass in order to back fill trapped voids in the rest of the trench, as will be described in further detail below.

Preferably, the semiconductor device has a plurality of recesses spaced apart along the length of the trench. The recesses may all extend from a first sidewall or at least one recess may extend from a first sidewall of the trench and at least one recess may extend from a second sidewall of the trench. At least one pair of opposing recesses may extend from opposing portions of the sidewalls.

Preferably, the depth of the trench is greater than or approximately equal to the width of the trench for portions of the trench other than at the or each recess. Preferably, the maximum width of the trench in the region of the or each recess is at least 1.1 times, or more preferably at least 1.2 times, the width of portions of the trench adjacent the respective recess. Preferably, the maximum width of the trench in the region of the or each recess is less than two times the width of portions of the trench adjacent the respective recess.

The cross section of the or each recess at the surface of the device may be rectilinear, triangular or arcuate. Preferably, the recess extends substantially or completely to the bottom of the trench.

Preferably, each pair, or the plurality, of recesses are at spaced apart locations along the length of the trench separated by less than 5 μm. More preferably, each pair, or the plurality, of recesses are separated by less than 3 μm

Preferably, the sidewalls are substantially vertical. Preferably, the material is electrically conductive. More preferably, the material is polysilicon. Preferably, the trench is at least half filled with the material. More preferably the trench is substantially filled with the material. The trench may intersect with at least one layer of material different to the material defining said surface. The trench may be lined with an electrically insulating material. The electrically insulating material may be silicon oxide. The semiconductor device may be a MOSFET or an IGBT.

Further objects and advantages of embodiments of the present invention will become apparent from the following description.

The present invention will now be described, by way of example only, with reference to the accompanying drawings, in which:

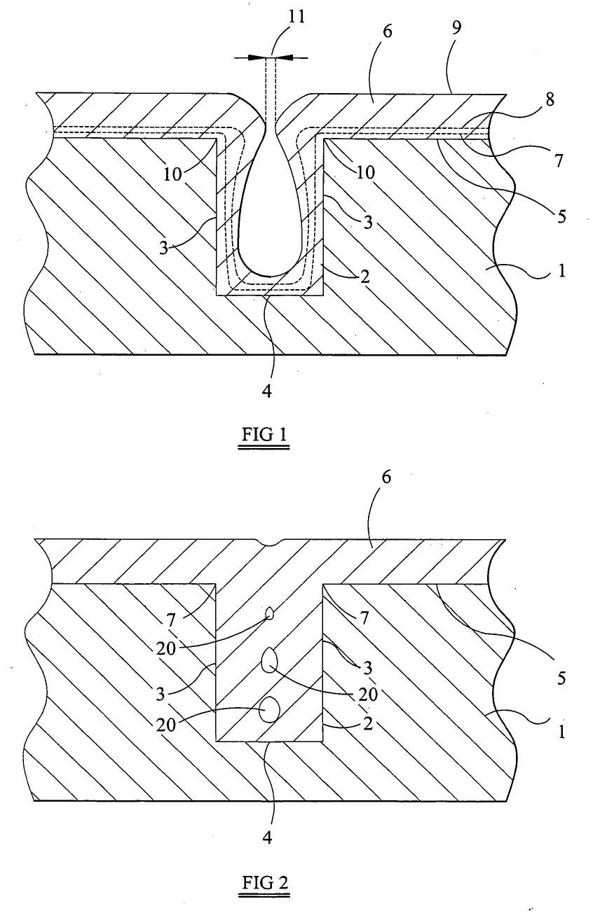

FIG. 1 schematically illustrates a cross sectional view of a conventional trench partly filled with a conductive material;

FIG. 2 schematically illustrates a cross sectional view of a conventional trench filled with a conductive material, depicting trapped voids;

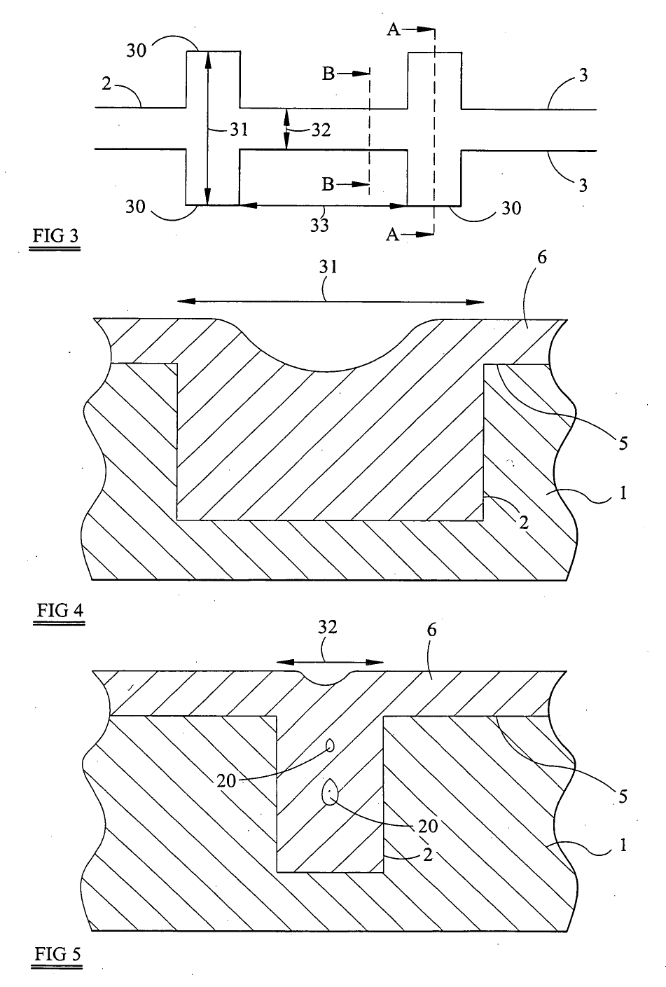

FIG. 3 schematically illustrates a plan view of a trench in accordance with a first embodiment of the present invention;

FIG. 4 schematically illustrates a cross sectional view of the trench of FIG. 3 along the line A-A in the direction of the arrows;

FIG. 5 schematically illustrates a cross sectional view of the trench of FIG. 3 along the line B-B in the direction of the arrows;

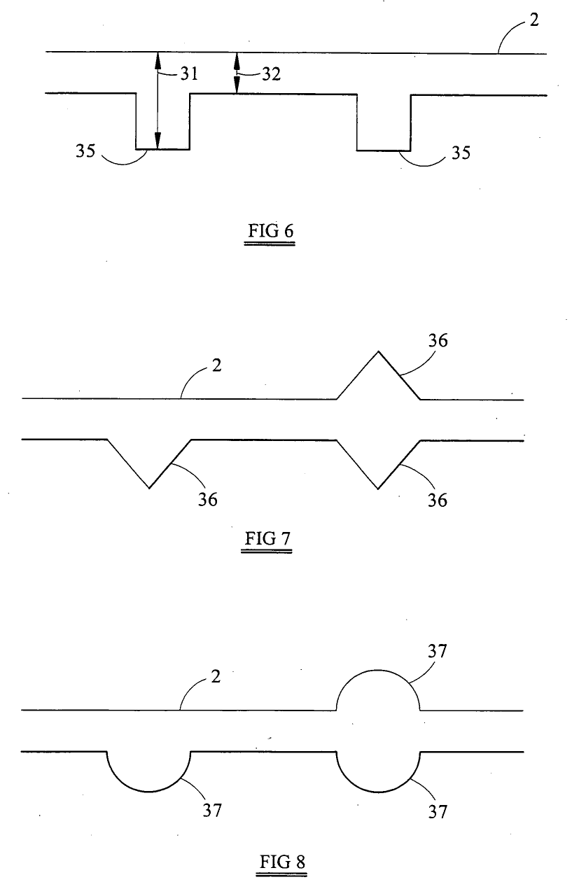

FIG. 6 schematically illustrates a plan view of a trench in accordance with a second embodiment of the present invention;

FIG. 7 schematically illustrates a plan view of a trench in accordance with a third embodiment of the present invention; and

FIG. 8 schematically illustrates a plan view of a trench in accordance with a fourth embodiment of the present invention.

Referring first to FIG. 1 this shows a semiconductor substrate 1 in which a trench 2 has been etched. For example, trench 2 may comprise a gate trench within a MOSFET. The method by which the trench has been etched may be entirely conventional, for instance by reactive ion etching (RIE) and as such will not be discussed further here.

Trench 2 has opposing sidewalls 3 and a base 4. The sidewalls 3 are shown as being substantially perpendicular to the upper surface 5 of the semiconductor substrate 1. The trench 2 is shown in cross section, with the longitudinal axis of the trench perpendicular to the plane of the drawing.

The sidewalls 3 extend along the length of the trench 2. The trench 2 has a depth, defined between the base 4 and the upper surface of the semiconductor substrate. The trench 2 also has a width defined at the upper surface 5 between the sidewalls 3.

The upper surface 5 of the substrate 1 is not necessarily exposed in the finished semiconductor device. Further layers of material may cover the upper surface during later manufacturing steps, such that it then defines a boundary between layers of material.

A layer of polysilicon 6 is deposited, by chemical vapour deposition from a source of polysilicon (not shown) located above the substrate 1, over the whole of an upper surface 5 of the semiconductor substrate 1. FIG. 1 depicts the upper surface of this deposited layer of polysilicon 6 at a number of intermediate steps 7, 8 and 9 partway through the deposition process.

The layer of polysilicon overlies the upper surface 5 and lines sidewalls 3 and base 4 of the trench 2. FIG. 1 illustrates the upper edges of the trench 10 attracting preferential deposition of polysilicon, relative to the lower regions of the sidewalls 3. This is as a consequence of the proximity of trench upper edges 10 to the source of the polysilicon, and the consequent greater flow of polysilicon vapour over this part of the trench.

Gap 11 represents the portion of the opening of trench 2 partway through the deposition of poly silicon within the trench. Polysilicon must pass through gap 11 in order to be deposited in the base 4 of the trench 2. Gap 11 is illustrated as closing down faster than the portion of the trench close to the base 4. This may be seen by the progression of successive layers of polysilicon 7, 8, 9 showing how the deposit of polysilicon is laid down over time. The layers of polysilicon are depicted as bulging out from the upper edges 10 of trench 2. Consequently, gap 11 is prone to closing off, and thereby restricting the passage of polysilicon vapour to the base 4 before the trench has fully filled.

For trenches with a high aspect ratio this problem of trench void creation is more serious due to the relatively larger region of trench left unfilled at the point at which gap 11 begins to close off. Additionally, trenches with slightly overhanging sidewalls are also more prone to the creation of voids due to an increased volume of trench to be filled for a given width of trench at the upper edge, compared with trenches having sidewalls normal to the surface of the substrate.

FIG. 2 illustrates a later stage in the deposition of polysilicon layer 6, whereby gap 11 has closed off preventing further access for the polysilicon to the lower regions of trench 2. Voids 20 remain in the polysilicon filled trench, as the chemical vapour deposition is not able to fill these once gap 11 has closed. Polysilicon 6 may form only a shallow layer within trench 2 coating the sidewalls 3 and the base 4. Alternatively, polysilicon may substantially or wholly fill the trench 2. The creation of voids within the polysilicon only becomes a problem when a significant amount of material has been deposited within the trench 2, for instance when greater than 50% of the volume of the trench 2 is filled by polysilicon.

Referring now to FIG. 3, this illustrates a modification of trench 2, whereby trench 2 is provided with spaced apart recesses 30 in accordance with a first embodiment of the present invention. Recesses 30 form recesses of the trench at the surface 5 resulting in a discrete localised increase in the trench width. Trench 2 extends from a first surface of the semiconductor device. Recesses 30 extend laterally into the sidewalls of the trench. Recesses 30 may extend substantially or completely to the bottom of the trench.

Recesses 30 allow the trench 2 to fill more evenly because the recesses 30 are less prone to closing off prematurely as gap 11 is initially wider than the gap for adjacent portions of the trench. As described above, the problem of trapped voids is reduced for trenches with a lower aspect ratio. Recesses 30 effectively comprise trench parts with a lower aspect ratio than the main portion of trench 2. Gap 11 between the upper edges of the recesses 30 closes more slowly than the equivalent gap 11 for the unmodified sections of the trench 2. Proportionally, more polysilicon must be deposited within the recesses 30 before they close off. Consequently, the recesses 30 of the trench 2 will remain open longer than adjacent sections of the trench of normal width. The provision of recesses 30 is of particular utility in reducing the presence of trapped voids when the depth of the trench is greater than or approximately equal to the width of the trench for portions of the trench other than at the or each recess.

In the narrower sections of the trench the trapped voids 20 tend to form passages extending along the length of the trench into the recesses 30. As the recesses 30 of trench 2 remain open after the point at which the narrower sections of the trench have closed off this leaves a route through to the passages that is back filled by polysilicon vapour.

As described above, recesses 30 effectively form sections of trench with a lower aspect ratio than the main portion of the trench. Consequently, the same reduction of trapped voids could be achieved by reducing the aspect ratio of the whole trench. However, this would necessarily require deviating from the optimum trench design, which may call for a high aspect ratio. Further, lower aspect ratio (i.e. wider) trenches consume a much larger proportion of the surface of the semiconductor device. The solution of the present invention, provides a significant reduction in the number and size of trapped voids, without consuming a significantly greater proportion of the surface area of the semiconductor device.

FIG. 4 illustrates a cross sectional view of the trench 2 of FIG. 3 along the line A-A in the direction of the arrows. Due to the wider width of the trench 31 in the region of recesses 30 (shown greatly exaggerated for clarity) the trench 2 is filled more evenly, and gap 11 remains open longer than is the case for the sections of trench 2 of normal width.

Referring now to FIG. 5, this illustrates a cross sectional view of the trench 2 of the FIG. 3 along the line B-B in the direction of the arrows. The cross sectional view of this part of the trench 2 of normal cross sectional width 32 is similar to the unmodified trench 2 of FIG. 2. Trapped voids 20 may be seen in cross section, forming passages as described above. However, due to the presence of the recesses of the trench 30 the size of the trapped voids 20 has been reduced as polysilicon vapour back fills the voids. The total number of trapped voids may similarly be reduced, and in many cases the trapped voids may be eliminated entirely.

After the trench 2 has been filled with polysilicon 6, the layer of polysilicon 6 may be exposed to further processing steps. This typically includes a process whereby the polysilicon overlying the upper surface 5 is at least partly removed. The polysilicon within trench 2 is not completely removed due to its greater depth. The upper surface of the polysilicon in trench 2 after etching may typically lie approximately in the same place as the upper surface 5 of the substrate.

In order to reduce the number and severity of trapped voids 20 that occur when trench 2 is filled with polysilicon it is preferable that the width 31 of the recesses 30 is greater than about 1.1 times the width 32 of the narrower sections of trench 2, (in FIG. 3 the recesses 30 are shown greatly exaggerated for clarity). For instance, periodic recesses with a maximum width greater than 1.2 times the width of the narrower sections have been shown to provide a significant reduction in trapped voids 20, while minimising the proportion of the surface area of the device consumed. It is the maximum width of the recesses that appears to be the most significant characteristic affecting the effectiveness in reducing void formation. The geometrical shape of the recesses may vary considerably. In FIG. 3 the recesses 30 are rectilinear, but other geometries may be equally effective.

For the polysilicon to be able to effectively back fill the trapped voids 20 it is necessary to ensure that the recesses are spaced sufficiently close together. Experimental evidence has shown that it is desirable that the gap 33 between recesses is less than about 5 μm. Gaps of 2.8 μm have proved to substantially eliminate the problems associated with trapped voids within polysilicon filled trenches.

FIG. 6 illustrates a second embodiment of the present invention, whereby recesses 35 of trench 2 each extend laterally from one side of the trench 2 only. As described above, the shape of the recesses is irrelevant. As a further modification, alternate recesses 35 could extend from opposite sides of the trench.

FIGS. 7 and 8 show examples of alternative shapes of recesses 30. FIG. 7 depicts triangular recesses 36. These are of particular interest as they represent the simplest shape to create using conventional photolithographic techniques. FIG. 8 depicts arcuate recesses 37. As it is the maximum width of the widened portion that is most significant, it will be obvious to the appropriately skilled person that the recesses may have a range of other shapes and geometries. Further, double sided recesses need not be symmetrical about the longitudinal axis of the trench. Recesses may be formed in pairs of opposing recesses, extending from opposing sidewalls of the trench 2.

As described above the problem of trapped voids within wholly, or partially, filled trenches is acute for steep walled or overhanging trenches. Therefore, the present invention has particular utility in improving the performance of semiconductor devices incorporating one or more trenches filled with conductive material, when the sidewalls of the trench are substantially vertical or overhanging.

A semiconductor device in accordance with the present invention, in addition to the filled trench, may comprise one or more regions within the semiconductor substrate of varying conductivity type. The trench may contact or intersect one or more of these regions having a material different to that found at the surface of the device.

Such a device may comprise a MOSFET or IGBT transistor. In that case the trench may comprise a gate trench contacting drain, source and body regions. Further, before filling with polysilicon the trench may be lined with silicon oxide, or other electrically insulating material. The trench may then be substantially or completely filled with polysilicon.

Additional processing steps may be incorporated in the production of the semiconductor device, before or after etching the trench or filling the trench. Such processing steps may include growing epitaxial layers of semiconductor or annealing.

It is not necessary that a trench has a base section in order for the benefits of the present invention to be achieved. The cross section of the trench may be of any shape, so long as at least one widened portion of the trench is incorporated.

In the described embodiments of the present invention the trenches have been described as having been filled with polysilicon. However, it will be readily apparent to the appropriately skilled person that any material which may be deposited by chemical vapour deposition within a trench may give rise to trapped voids. Therefore the present invention will have utility in reducing trapped voids in any such trench fill material.

Further modifications, and applications, of the present invention will be readily apparent to the appropriately skilled person, without departing from the scope of the appended claims.

1. A semiconductor device, comprising:
a trench extending into the device from a surface, the trench having sidewalls extending along the length of the trench, the trench having a depth, the trench having a width defined at said surface between said sidewalls, and the trench being at least partly filled with a material;
wherein at least one of the sidewalls is provided with at least one lateral recess, the or each recess providing a discrete localised increase in said trench width.

2. A semiconductor device according to claim 1, wherein the at least one recess comprises a plurality of recesses spaced apart along the length of the trench.

3. A semiconductor device according to claim 2, wherein the recesses all extend from a first sidewall.

4. A semiconductor device according to claim 2, wherein at least one recess extends from a first sidewall of the trench and at least one recess extends from a second sidewall of the trench.

5. A semiconductor device according to claim 4, wherein the device is provided with at least one pair of opposing recesses extending from opposing portions of the sidewalls.

6. A semiconductor device according to claim 1, wherein the depth of the trench is greater than or approximately equal to the width of the trench for portions of the trench other than at the or each recess.

7. A semiconductor device according to claim 1, wherein the maximum width of the trench in the region of the or each recess is at least 1.1 times the width of portions of the trench adjacent the respective recess.

8. A semiconductor device according to claim 7, wherein the maximum width of the trench in the region of the or each recess is at least 1.2 times the width of portions of the trench adjacent the respective recess.

9. A semiconductor device according to claim 1, wherein the maximum width of the trench in the region of the or each recess is less than two times the width of portions of the trench adjacent the respective recess.

10. A semiconductor device according to claim 1, wherein at least one recess has a rectilinear cross section at the surface of the device.

11. A semiconductor device according to claim 1, wherein at least one recess has a triangular cross section at the surface of the device.

12. A semiconductor device according to claim 1, wherein at least one recess has an arcuate cross section at the surface of the device.

13. A semiconductor device according to claim 1, wherein the or each recess extends substantially to the bottom of the trench.

14. A semiconductor device according to claim 1, wherein the or each recess extends to the bottom of the trench.

15. A semiconductor device according to claim 1, wherein the device is provided with at least two recesses at spaced apart locations along the length of the trench separated by less than 5 μm.

16. A semiconductor device according to claim 15, wherein the device is provided with a plurality of recesses at spaced apart locations along the length of the trench, with adjacent pairs of recess separated by less than 5 μm.

17. A semiconductor device according to claim 1, wherein the device is provided with at least two recesses at spaced apart locations along the length of the trench separated by less than 3 μm.

18. A semiconductor device according to claim 17, wherein the device is provided with a plurality of recesses at spaced apart locations along the length of the trench, with adjacent pairs of recess separated by less than 3 μm.

19. A semiconductor device according to claim 1, wherein the sidewalls are substantially vertical.

20. A semiconductor device according to claim 1, wherein the material is an electrically conductive material.

21. A semiconductor device according to claim 20, wherein the material is polysilicon.

22. A semiconductor device according to claim 1, wherein the trench is at least half filled with the material.

23. A semiconductor device according to claim 1, wherein the trench is substantially filled with the material.

24. A semiconductor device according to claim 1, wherein the trench intersects at least one layer of material different to the material defining said surface.

25. A semiconductor device according to claim 1, wherein the trench is lined with an electrically insulating material.

26. A semiconductor device according to claim 25, wherein the electrically insulating material is silicon oxide.

27. A semiconductor device according to claim 1, wherein the device is a MOSFET or an IGBT.

28. A method of fabricating a semiconductor device, the method comprising:
a) forming a trench extending from a first surface of the device, the trench having sidewalls extending to a depth below the surface, and having a width defined at said surface between said sidewalls, at least one of the sidewalls being provided with at least one recess, the or each recess providing a discrete localised increase in said trench width; and
b) at least partly filling the trench with a first material by chemical vapour deposition.
